(19) United States
(12) Patent Application Publication
(10) Pub. No.: US 2023/0307564 A1
(43) Pub. Date: Sep. 28, 2023

(54) BACKSHEET, SOLAR MODULE AND USE OF A DYE

(71) Applicants: HANWHA Q CELLS GMBH, Bitterfeld-Wolfen (DE); HANWHA Q CELLS & ADVANCED MATERIALS CORP., Seoul (KR)

(72) Inventors: Marcel KÜHNE, Bitterfeld-Wolfen (DE); Seung-Ho JEONG, Seoul (KR); Yohw LEE, Seoul (KR); Ye Seop SHIN, Seoul (KR)

(21) Appl. No.: 18/043,537

(22) PCT Filed: Sep. 1, 2021
(86) PCT No.: PCT/EP2021/074154

§ 371 Date: Feb. 28, 2023

(30) Foreign Application Priority Data
Sep. 1, 2020 (DE) 10 2020 122 805.8

(51) Int. Cl. H01L 31/049; H01L 31/048

(52) U.S. Cl. CPC H01L 31/049; H01L 31/0481

(57) ABSTRACT

A backsheet for a solar module having a sequence of layers one above the other in specified order, including: a polyvinyl fluoride layer; an adhesive layer arranged on the polyvinyl fluoride layer; a polymer core layer arranged on the adhesive layer; a further adhesive layer arranged on the polymer core layer; and a further polyvinyl fluoride layer. The polyvinyl fluoride layer is transparent and the adhesive layer and/or the further adhesive layer comprises a dye. Further, the invention relates to a solar module comprising such a backsheet. Furthermore, the invention relates to a use of a dye in an adhesive layer and a transparent polyvinyl fluoride layer for forming a backsheet of a solar module.

### RELATED APPLICATIONS

The present application is a National Phase entry of PCT Application No. PCT/EP2021/074154, filed Sep. 1, 2021, which claims priority to German Patent Application No. 10 2020 122 805.8, filed Sep. 1, 2020, the disclosures of which are hereby incorporated by reference herein in their entirety.

### FIELD OF THE INVENTION

The invention relates to a backsheet, to a solar module comprising such a backsheet and to a use of a dye. The invention relates to a backsheet for a solar module having a sequence of layers one above the other in specified order, comprising:
a polyvinyl fluoride layer;
an adhesive layer arranged on the polyvinyl fluoride layer;
a polymer core layer arranged on the adhesive layer;
a further adhesive layer arranged on the polymer core layer; and
a further polyvinyl fluoride layer. Furthermore, the invention relates to a solar module comprising such a backsheet, and to a use of a dye for forming such a backsheet.

### BACKGROUND OF THE INVENTION

The polyvinyl fluoride layer and the further polyvinyl fluoride layer are very stable and weather-resistant materials. The polymer core layer strengthens the material qualities of the two polyvinyl fluoride layers, whereas the adhesive layers provide a long-term adhesiveness between the polymer core layer and each of the polyvinyl fluoride layers.

A solar module has a frontsheet, a backsheet and solar cells arranged in electrically coupled so called strings. The frontsheet is arranged on a light-entering side of the solar module and the backsheet is arranged on a solar module backside opposite to the light-entering side. The solar cells are arranged between the frontsheet and the backsheet. The frontsheet is made of materials which are transparent with respect to the spectrum of the sunlight that can be converted into electricity by the solar cells. Therefore, the appearance and/or color of a solar module which is seen during use and/or operation is significantly determined by the color of the solar cells and the solar module's backsheet. Solar cells are of dark appearance such as of dark blue color or of black color. Polyvinyl fluoride layer is only available as transparent layer or of white color or of grey color. As there are spaces between the solar cells which are visible to the human eye, often the visual appearance of a solar module is not satisfying under aesthetical reasons. Therefore, a customer demand for improved aesthetical appearances of solar modules exist.

### SUMMARY

It is an object of the invention to provide a backsheet and a solar module provide an improved aesthetical appearance to the human eye.

This problem is solved by a backsheet, a solar and a use of a dye having the features according to the claims.

By combining a transparent polyvinyl fluoride layer with an adhesive layer comprising a dye, the backsheet can be provided in any color, especially a color wanted by customers having specific aesthetical requirements.

According to the invention the polyvinyl fluoride layer is transparent and the adhesive layer comprises a dye and/or the further adhesive layer comprises a dye.

The dye of the adhesive layer and/or the dye of the further adhesive layer can be the same or different. Preferably the adhesive layer comprises the dye. Thereby, the adhesive layer comprising the dye thereby protects the polymer core layer from damages caused by certain sunlight wavelengths, especially when sunlight first enters the transparent polyvinyl fluoride layer, then the dye-containing adhesive layer and subsequently the polymer core layer.

The dye can render the adhesive layer and/or the further adhesive layer to show any color. According to a preferred embodiment, the dye is chosen such that the adhesive layer and/or the further adhesive layer is of black color. The formulation “black color” is intended to mean a dark color comprising also dark blue or dark green or dark red. When the adhesive layer and/or the further adhesive layers are of black color, a solar module, in which the backsheet is integrated, has a black appearance to the human eye seen from the frontsheet side so that the solar cells of the solar module are not visible by the human eye provided that the solar cells appear in the same color as the backsheet.

There exist some color systems such as Pantone, HSK, RAL in order to define each color according to a classification. Preferably the adhesive layer and/or the further adhesive layer are of a color corresponding to RAL 5004, RAL 7016, RAL 7021, RAL 8002, RAL 9004, RAL 9005, RAL 9011 or RAL 9017 according to RAL Classic from RAL Deutsches Institut für Gütesicherung and Kennzeichnung e.V. (Bonn, Germany).

Preferably, the dye is chosen from a group consisting of molecular dyes and pigment dyes. The dye can be graphite, carbon black, or aniline black dye. Preferably, the dye is carbon black.

According to a preferred embodiment, the further polyvinyl fluoride layer is of white color. Polyvinyl fluoride layers are commercially available under “Tedlar®” from DuPont de Nemours Co. (Wilmington, USA). The are available in white, grey color or transparent.

Preferably, the polymer core layer is made of polyester. More preferably, the polymer core layer is made of polyethylene terephthalate. Such a polymer core layer provides a good material quality for the backsheet.

In a preferred embodiment, the polyvinyl fluoride layer and the further polyvinyl fluoride layer each have a thickness in the range of 10 to 40 μm, more preferably 20 to 30 μm. Preferably, the adhesive layer and the further adhesive layer each have a thickness in the range of 5 to 25 μm, more preferably 10 to 20 μm. Preferably, the polymer core layer has a thickness in the range of 200 bis 300 μm, more preferably, 230 to 270 μm. By having these layer dimensions, the backsheet provides long-term stability and is long-term weather-resistant.

Preferably, the backsheet has an inner side designed to face to an inside of the solar module, when integrated into the solar module, and an air side opposite to the inner side, wherein the polyvinyl fluoride layer forms the inner side and the further polyvinyl fluoride layer forms the air side. More preferably, the adhesive layer then contains the dye.

One or more intermediate layers can be arranged between and/or on the sequence of layers. Preferably, the backsheet consists of the sequence of layers one above the other in specified order, comprising:
the polyvinyl fluoride layer;
the adhesive layer arranged on the polyvinyl fluoride layer;
the polymer core layer arranged on the adhesive layer;
the further adhesive layer arranged on the polymer core layer; and
the further polyvinyl fluoride layer.

Each of the polyvinyl fluoride layer, the adhesive layer, the polymer core layer, the further adhesive layer, and the further polyvinyl fluoride layer can comprise one or more additives such as filler, stabilizer, plasticizer, elasticator, extender, processing agent, anti-agent chemical etc. Consequently, corresponding material properties can be changed or further enhanced, respectively.

Furthermore, the invention relates to a solar module, comprising the backsheet according to one or more of the above embodiments.

Embodiments and advantages described in relation to the backsheet apply accordingly the solar module using such backsheets and vice versa.

Preferably, the solar module comprises the backsheet, wherein the backsheet has an inner side designed to face to an inside of the solar module, when integrated into the solar module, and an air side opposite to the inner side, wherein the polyvinyl fluoride layer forms the inner side and the further polyvinyl fluoride layer forms the air side. This is advantageous because the polyvinyl fluoride layer is chosen to be transparent so that a human when looking onto the light-entering side sees the solar cells and the backsheet layer comprising the dye in at least one of the adhesive layers.

In a preferred embodiment, the solar module comprises one above the other in the specified order: the backsheet, a back encapsulation layer, solar cells, a front encapsulation layer, and a frontsheet. The back encapsulation layer is arranged on the inner side of the backsheet so that the air side of the backsheet faces away from the back encapsulation layer. The solar cells are arranged on a side of the back encapsulation layer facing away from the backsheet. The front encapsulation layer is arranged on a side of the solar cells facing away from the backsheet, whereas the frontsheet is arranged on a side of the front encapsulation layer facing away from the backsheet. Preferably, a material of the back encapsulation layer and the front encapsulation layer is ethylene vinyl acetate. A frontsheet material can be plastic. Preferably, the frontsheet material made of glass being highly transparent for the sunlight wavelength spectrum that is to be converted by the solar cells.

Furthermore, the invention relates to a use of a dye in an adhesive layer together with a transparent polyvinyl fluoride layer for forming a backsheet for a solar module. The dye is preferably chosen from a group consisting of graphite, carbon black, or aniline black dye. More preferably, the dye is carbon black.

### BRIEF DESCRIPTION OF THE DRAWINGS

The invention will be understood more fully from the detailed description given hereinafter and from the accompanying figures. The figures are only schematic and not true to scale.

They show:

FIG. 1 a cross-sectional view of an inventive backsheet; and

FIG. 2 a cross-sectional view of an inventive solar module comprising the backsheet shown in FIG. 1.

### DETAILED DESCRIPTION

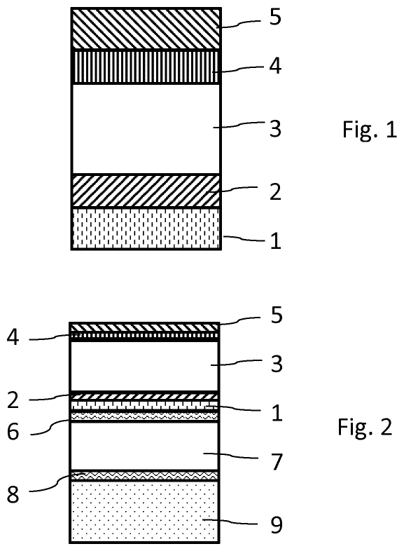

FIG. 1 shows a cross-sectional view of an inventive backsheet. The backsheet has a sequence of layers one above the other in specified order, comprising:
a polyvinyl fluoride layer 1;
an adhesive layer 2 arranged on the polyvinyl fluoride layer 1;
a polymer core layer 3 arranged on the adhesive layer 2;
a further adhesive layer 4 arranged on the polymer core layer 3; and
a further polyvinyl fluoride layer 5.

The polyvinyl fluoride layer 1 is transparent. The adhesive layer 2 comprises a dye so that it is of black color. Additionally or alternatively, the further adhesive layer 5 can comprise the dye. The further polyvinyl fluoride layer 5 is of white color. Material of polymer core layer 3 is polyethylene terephthalate. The backsheet has surface dimensions in order to be a backsheet for a solar module.

FIG. 2 shows a cross-sectional view of an inventive solar module comprising the backsheet shown in FIG. 1. The backsheet has an inner side designed to face to an inside of the solar module, when integrated into the solar module, and an air side opposite to the inner side, wherein the polyvinyl fluoride layer 1 forms the inner side and the further polyvinyl fluoride layer 5 forms the air side. The inner side of the backsheet is arranged on a back encapsulation layer 6, wherein the air side of the backsheet faces away from the back encapsulation layer 6. Solar cells 7 are arranged on a side of the back encapsulation layer 6 facing away from the backsheet. Further, a front encapsulation layer 8 is arranged on a side of the solar cells 7 facing away from the backsheet, and a frontsheet 9 is arranged on a side of the front encapsulation layer 8 facing away from the backsheet.

### REFERENCE NUMERALS

1 polyvinyl fluoride layer
2 adhesive layer
3 polymer core layer
4 further adhesive layer
5 further polyvinyl fluoride layer
6 back encapsulation layer
7 solar cells
8 front encapsulation layer
9 frontsheet

1. A backsheet for a solar module having a sequence of layers one above the other in specified order, comprising:
a polyvinyl fluoride layer;
an adhesive layer arranged on the polyvinyl fluoride layer;
a polymer core layer arranged on the adhesive layer;
a further adhesive layer arranged on the polymer core layer;
a further polyvinyl fluoride layer;
wherein the polyvinyl fluoride layer is transparent; and
wherein the adhesive layer comprises a dye and/or the further adhesive layer comprises a dye.

2. The backsheet according to claim 1, wherein the dye is chosen such that the adhesive layer and/or the further adhesive layer (5) is of black color.

3. The backsheet according to claim 1, wherein the dye is chosen from a group consisting of molecular dyes and pigment dyes.

4. The backsheet according to claim 1, wherein the further polyvinyl fluoride layer is a white color.

5. The backsheet according to claim 1, wherein the polymer core layer is made of polyester.

6. The backsheet according to claim 1, wherein the polyvinyl fluoride layer and the further polyvinyl fluoride layer each have a thickness in a range of 10 to 40 μm.

7. A solar module, comprising the backsheet according to claim 1.

8. The backsheet according to claim 1, wherein the backsheet has an inner side designed to face to an inside of the solar module, when integrated into the solar module, and an air side opposite to the inner side, wherein the polyvinyl fluoride layer forms the inner side and the further polyvinyl fluoride layer forms the air side.

9. A method of forming a backsheet for a solar module, including using a dye in an adhesive layer and a transparent polyvinyl fluoride layer to form the backsheet.

10. The backsheet according to claim 1, wherein the polymer core layer is made of polyethylene terephthalate.

11. The backsheet according to claim 1, wherein the polyvinyl fluoride layer and the further polyvinyl fluoride layer each have a thickness in a range of 20 to 30 μm.

12. The solar module according to claim 7, wherein the backsheet has an inner side designed to face to an inside of the solar module, when integrated into the solar module, and an air side opposite to the inner side, wherein the polyvinyl fluoride layer forms the inner side and the further polyvinyl fluoride layer forms the air side.
